(19) United States
(12) Patent Application Publication
(10) Pub. No.: US 2013/0258619 A1
(43) Pub. Date: Oct. 3, 2013

(54) STIFFENER FRAME WITH CIRCUIT BOARD CORNER PROTECTION

(71) Applicants: Tom J. Ley, Cupertino, CA (US); Eric S. Tosaya, Fremont, CA (US); Chia-Ken Leong, Fremont, CA (US)

(72) Inventors: Tom J. Ley, Cupertino, CA (US); Eric S. Tosaya, Fremont, CA (US); Chia-Ken Leong, Fremont, CA (US)

(21) Appl. No.: 13/436,177

(22) Filed: Mar. 30, 2012

(51) Int. Cl. H05K 7/14; H05K 3/00

(52) U.S. Cl. 361/753; 29/829

(57) ABSTRACT

Various circuit boards and stiffener frames and methods of making the same are disclosed. In one aspect, a method of manufacturing is provided that includes fabricating a stiffener frame that has a surface adapted to engage a side of a circuit board. The surface includes a projection to protect a corner of the circuit board.

### BACKGROUND OF THE INVENTION

1. Field of the Invention

This invention relates generally to semiconductor processing, and more particularly to circuit boards with stiffener frames and to methods of making the same.

2. Description of the Related Art

Many current integrated circuits are formed as multiple die on a common silicon wafer. After the basic process steps to form the circuits on the die are complete, the individual die are cut from the wafer. The cut die are then usually mounted to structures, such as circuit boards, or packaged in some form of enclosure.

One frequently-used package consists of a substrate upon which a die is mounted. The upper surface of the substrate includes electrical interconnects. The die is manufactured with a plurality of bond pads. A collection of solder bumps are provided between the bond pads of the die and substrate interconnects to establish ohmic contact. An underfill material is deposited between the die and the substrate to act as a material that prevents damage to the solder bumps due to mismatches in the coefficients of thermal expansion between the die and the substrate, and an adhesive to hold the die. The substrate interconnects include an array of solder pads that are arranged to line up with the die solder bumps. After the die is seated on the substrate, a reflow process is performed to enable the solder bumps of the die to metallurgically link to the solder pads of the substrate. After the die is mounted to the substrate, a lid is attached to the substrate to cover the die. For lidless designs, a heat spreader plate is sometimes placed in thermal contact with the mounted die. Some conventional integrated circuits, such as microprocessors and graphics processors, generate sizeable quantities of heat that must be ferried away to avoid device shutdown or damage. For these devices, the lid serves as both a protective cover and a heat transfer pathway.

One conventional type of substrate consists of a core laminated between upper and lower build-up layers. The core itself usually consists of four layers of glass filled epoxy. The build-up layers, which may number four or more on opposite sides of the core, are formed from some type of resin. Various metallization structures are interspersed in the core and build-up layers in order to provide electrical pathways between pins or pads on the lowermost layer of the substrate and pads that bond with the chip solder bumps.

The core provides a certain stiffness to the substrate. Even with that provided stiffness, conventional substrates still tend to warp due to mismatches in coefficients of thermal expansion for the chip, underfill and substrate. However, there is a need to provide shorter electrical pathways in package substrates in order to lower power supply inductance and improve power fidelity for power transferred through the substrate. The difficult problem is how to reduce the electrical pathways without inducing potentially damaging substrate warping.

One conventional technique for reducing electrical pathways is to use so-called “coreless” substrates. While coreless substrates may provide more favorable electrical characteristics than a comparably sized substrate with a core, their very thinness can lead to greater warpage and greater risk of substrate damage, particularly at the substrate corners. Conventional substrate corners are typically at or very near 90°. During the many processing steps to complete a packaged part, the substrate is frequently picked up, moved, and put down. These movements can damage the delicate corners.

One conventional technique to reduce substrate warpage is the usage of a stiffener frame on the substrate. Conventional stiffener frames are typically flat frames mounted on the substrate so that the substrate corners are still exposed to impacts.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes fabricating a stiffener frame that has a surface adapted to engage a side of a circuit board. The surface includes a projection to protect a corner of the circuit board.

In accordance with another aspect of an embodiment of the present invention, an apparatus is provided that includes a stiffener frame that has a surface adapted to engage a side of a circuit board. The surface includes a projection to protect a corner of the circuit board.

In accordance with another aspect of an embodiment of the present invention, an apparatus is provided that includes a circuit board that has a side and a corner. A stiffener frame is positioned on the side and has a projection to protect the corner.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary conventional semiconductor chip package that includes a semiconductor chip mounted on a package substrate;

FIG. 2 is an exploded pictorial view of an exemplary embodiment of a semiconductor chip device that may include a semiconductor chip flip-chip or otherwise mounted to a circuit board and a stiffener frame also mounted to the circuit board;

FIG. 3 is a pictorial view of corner portions of the exemplary circuit board and stiffener frame depicted in FIG. 2;

FIG. 4 is a pictorial view like FIG. 3, but of corner portions of an alternate exemplary circuit board and stiffener frame;

FIG. 5 is a partially exploded pictorial view of an alternate exemplary embodiment of a semiconductor chip device that may include a semiconductor chip flip-chip or otherwise mounted to a circuit board and a stiffener frame also mounted to the circuit board;

FIG. 6 is a pictorial view like FIG. 3, but of corner portions of another alternate exemplary circuit board and stiffener frame; and

FIG. 7 is a pictorial view of an exemplary semiconductor chip device and an electronic device and depicts schematic mounting of the semiconductor chip device in the electronic device.

### DETAILED DESCRIPTION OF SPECIFIC EMBODIMENTS

Various embodiments of a semiconductor chip device are disclosed. One example includes a semiconductor chip mounted to a circuit board. A stiffener frame is also mounted to the circuit board. The stiffener frame includes projections designed to protect one or more corners of the circuit board. The corners of the circuit board may be notched in a concave arrangement or rounded to facilitate protection by the frame projections. Additional details will now be described.

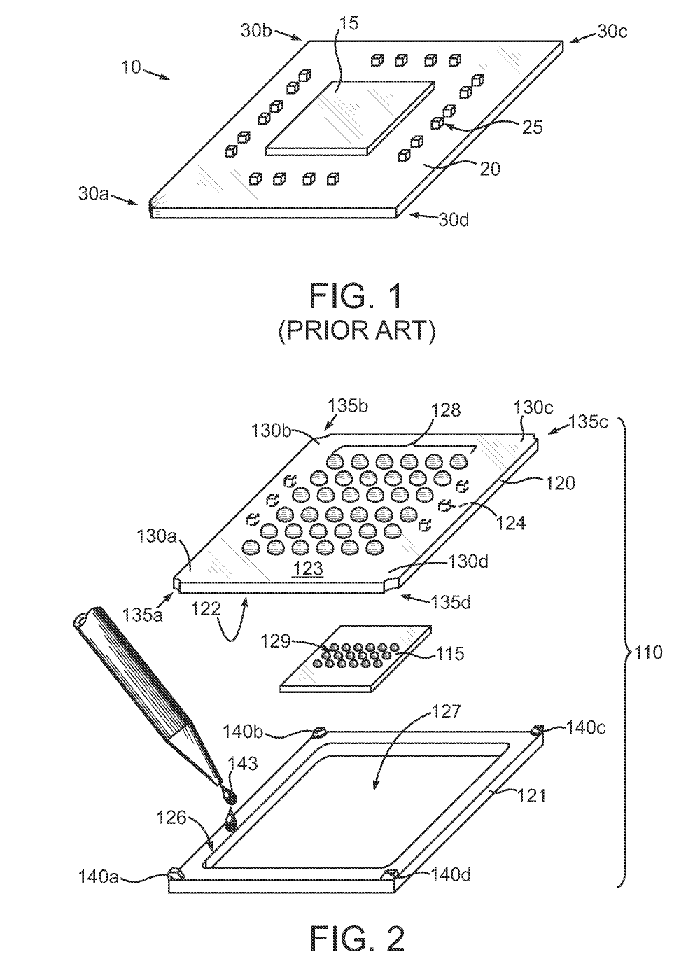

In the drawings described below, reference numerals are generally repeated where identical elements appear in more than one figure. Turning now to the drawings, and in particular to FIG. 1, which is a pictorial view of an exemplary conventional semiconductor chip package 10 that includes a semiconductor chip 15 mounted on a package substrate 20. The upper surface of the package substrate 20 may be populated with plural capacitors 25. The circuit board 20 is a buildup design that consists of plural layers of resin and metal interconnects built up on opposite sides of a core. The circuit board 20 has a generally rectangular footprint that includes four corners 30a, 30b, 30c and 30d. The corners 30a, 30b, 30c and 30d are usually created when the circuit board 20 is singulated from a strip of multiple circuit boards. Following singulation, the circuit board 20 is typically subjected to a variety of processing steps, such as chip mounting, inspection, component mounting and others. Many of these processes require the circuit board 20 to be picked up, put down and otherwise moved from place to place. The corners 30a, 30b, 30c and 30d are susceptible to damage during these various processing and transporting steps. For example, the corner 30a is depicted in a damaged state. Corner damage can lead to crack propagation and if severe enough can actually damage some of the electrical interconnects that are embedded within the circuit board 20.

An exemplary embodiment of a semiconductor chip device 110 that compensates for the potential for circuit board corner damage is depicted in exploded pictorial form in FIG. 2. Here, the semiconductor chip device 110 may include a semiconductor chip 115 flip-chip or otherwise mounted to a circuit board 120 and a stiffener frame 121 also mounted to the circuit board 120. The circuit board 120 includes a top side 122 and a bottom side 123, but note that the circuit board 120 and the semiconductor chip 115 are shown flipped over from the orientation of the conventional circuit board 20 and chip 15 depicted in FIG. 1 so that the bottom side 123 is visible and the top side 122 is obscured. The semiconductor chip 115 and the stiffener frame may both be mounted to the top side 122. In addition, the top side 122 may be populated with plural components 124, which may be passive devices like capacitors, inductors or resistors, or active devices, such as integrated circuits. The stiffener frame 121 in this illustrative embodiment includes a flat seating surface 126 to seat on the circuit board 120 and vice versa, and a central opening 127 sized to accommodate one more electronic components, which might include the semiconductor chip 115 and the components 124. The circuit board 120 may have a square, rectangular or other footprint.

The semiconductor chip 115 and any alternatives thereof disclosed herein may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 115 may be constructed of bulk semiconductor, such as silicon or germanium, or semiconductor on insulator materials, such as silicon-on-insulators materials. The semiconductor chip 115 may be flip-chip mounted to the circuit board 120 and electrically connected thereto by solder joints, conductive pillars or other structures (not shown). Optionally, wire bonding may be used.

The circuit board 120 may be a package substrate or other type of printed circuit board as described elsewhere herein. Monolithic or buildup structures may be used. If a buildup design is used, the circuit board 120 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. The number of layers in the circuit board 120 can vary from four to sixteen or more, although less than four may be used. So-called “coreless” designs may be used as well. Indeed, coreless or other types of designs may benefit from the stiffness provided by the stiffener frame 121. The layers of the circuit board 120 consist of an insulating material, such as various well-known epoxies or other resins, interspersed with metal interconnects. A multi-layer configuration other than buildup could be used. Optionally, the circuit board 120 may be composed of well-known ceramics or other materials suitable for package substrates or other printed circuit boards.

To facilitate electrical interface with other circuit boards or devices, the circuit board 120 may be provided with an interconnect arrangement, such as the depicted ball grid array 128 projecting from the bottom side 123. However, other types of interconnects may be used, such as pin grid arrays, land grid arrays or other types. The semiconductor chip 115 may be electrically interfaced with the circuit board 120 by way of plural interconnect structures 129, which may be solder joints, copper conductive pillars with or without solder or other interconnect structures. The semiconductor chip 115 may be covered with a lid or glob top or have another type of encapsulant (not shown).

Still referring to FIG. 2, each corner 130a, 130b, 130c and 130d of the circuit board 120 may be provided with a concave notch 135a, 135b, 135c and 135d. The notches 135a, 135b, 135c and 135d are designed to accommodate corresponding corner projections 140a, 140b, 140c and 140d of the stiffener frame 121. The circuit board 120 is designed to seat on the stiffener frame 121 and vice versa with the notches 135a, 135b, 135c and 135d accommodating the projections 140a, 140b, 140c and 140d. The notches 135a, 135b, 135c and 135d eliminate the potentially troublesome 90° corners 30a, 30b, 30c and 30d of the conventional design shown in FIG. 1 that are prone to damage. Furthermore, the projections 140a, 140b, 140c and 140d of the stiffener frame 121 protect the corners 130a, 130b, 130c and 130d from external impacts. In addition of course, the stiffener frame 121 functions like traditional stiffener frames in that it stiffens what otherwise might be a relatively flexible circuit board 120 particularly if the circuit board 120 is configured as a coreless organic substrate. Also, the projections can provide quick self alignment capability to align the circuit board 120 with the stiffener frame 121. The stiffener frame 121 and disclosed alternatives thereof may be secured to the top side 122 of the circuit board 120 by an adhesive 143. The adhesive 143 may be a well-known epoxy or other type of polymeric adhesive or even a solder if the stiffener frame 121 and the circuit board 120 can tolerate solder application.

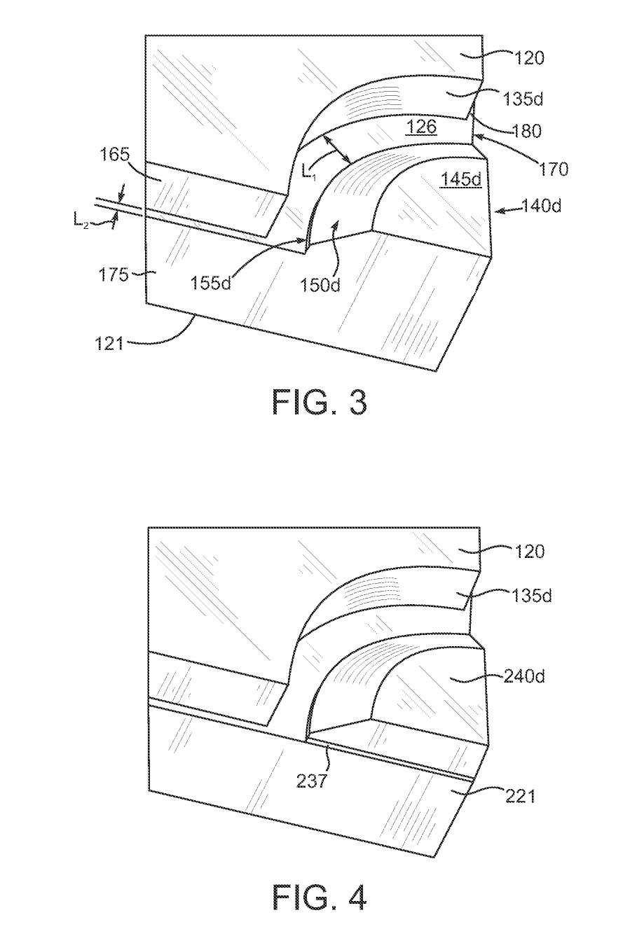

Attention is now turned to FIG. 3, which is a pictorial view of portions of the circuit board 120 and the stiffener frame 121 that include the notch 135d and the projection 140d. The following discussion of the notch 135d and the projection 140d of the stiffener frame 121 will be illustrative of the remainder of the circuit board 120 and the stiffener frame 121. The projection 140d may include an upper flat surface 145d that transitions to an arcuate slope surface 150d. The arcuate surface 150d may transition to a vertical arcuate surface 155d that terminates at the seating surface 126 of the stiffener frame 121 or may transition directly to the seating surface 126. In either case, the arcuate surface 150d provides a sloped surface to facilitate positioning of the notch 135d. The notch 135d of the circuit board 120 may be sized so that there is a set back of dimension L₁ from the vertical arcuate surface 155d. The actual size of the set back L₁ may be quite small, perhaps on the order of a millimeter or less. In addition, the edges 165 and 170 of the circuit board 120 may be set back a small distance L₂ from the edges 175 and 180 of the stiffener frame 121. By making the external footprint of the stiffener frame 121 large enough to provide the setbacks L₂ from the edges 165 and 170, those same edges 165 and 170 and the other edges not shown in FIG. 3 are protected from damage. Optionally, there need be no set back L₂ at all. The notch 135d may be formed in the circuit board 120 by mechanical sawing, stamp punching, laser cutting or etching techniques as desired, or even by molding or during a build up process.

The stiffener frame 121 may be composed of a variety of materials, such as, for example, aluminum, copper, stainless steel, nickel, alloys of these or the like. Steel-nickel alloys, such as Invar, may provide favorably low thermal expansion. Optionally, well-known plastics may be used. In this illustrative embodiment, the projection 140d may be integrally formed with the stiffener frame 121. For example, the projection 140d may be formed by stamping, forging, casting, molding or machining or some combination of such processes as desired.

In the illustrative embodiment depicted in FIG. 3 and described above, the projection 140d of the stiffener frame 121 is integrally formed with the stiffener frame 121. However, it may be possible to separately fabricate a projection and thereafter mount it to a stiffener frame. In this regard, attention is now turned to FIG. 4, which is a pictorial view like FIG. 3 but of an alternate exemplary embodiment of a stiffener frame 221 that includes a projection 240d that is secured to the stiffener frame 221 by an adhesive 237. The adhesive 237 may be a well-known epoxy or other type of polymeric adhesive or even a solder if the stiffener frame 221 and the projection 240d are composed of metallic materials. However, the projection 240d and the stiffener frame 221 may be composed of disparate materials such as various metallic materials or various types of plastics in which case the adhesive 237 may be some type of polymeric material that is capable of joining metallic and non-metallic materials. Like the other disclosed embodiments, the circuit board 120 is provided with the notch 135d as described above.

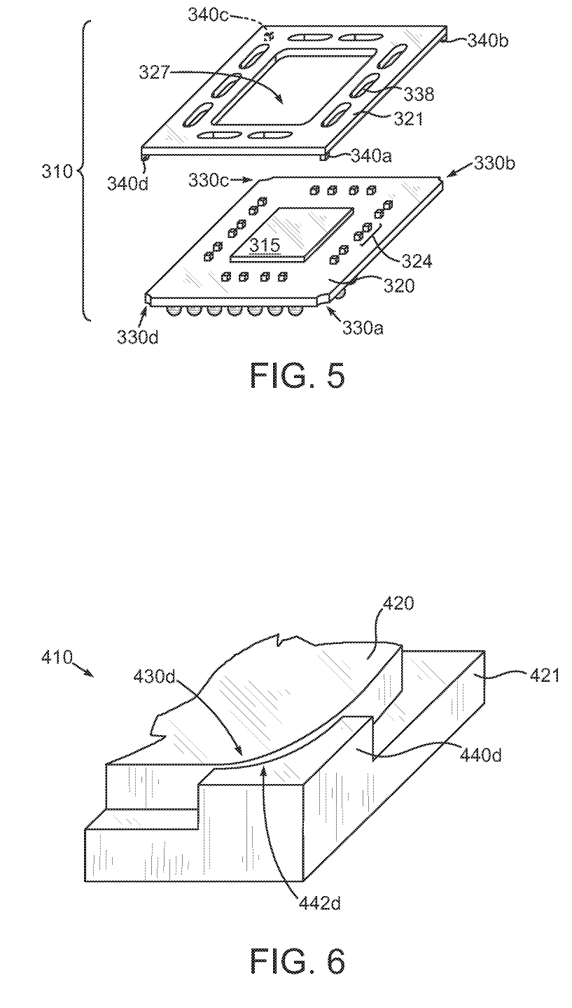

Another alternate exemplary embodiment of a semiconductor chip device 310 may be understood by referring now to FIG. 5, which is a partially exploded pictorial view. Here, the semiconductor chip device 310 may include a semiconductor chip 315 mounted on a circuit board 320 and a stiffener frame 321 also mounted on the circuit board 320 or vice versa. The semiconductor chip 315 and the circuit board 320 may be configured as described elsewhere herein for the other exemplary embodiments and thus include corners 330a, 330b, 330c and 330d and notches 335a, 335b, 335c and 335d. Since the circuit board 320 is flipped over from the orientation of the circuit board 120 depicted in FIG. 2, both the semiconductor chip 315 and various components 324 are visible. The components 324 may be like the components 124 described above. Again, a ball grid array 322 may be used to interface the circuit board 320 with some other electrical device not shown. In this illustrative embodiment, the stiffener frame 321 may include a central opening 327 to accommodate the semiconductor chip 315 and projections 340a, 340b, 340c and 340d to provide structural protection as described above. Note that the fourth projection 340c is not visible and shown dashed. However, unlike the stiffener frame 121 depicted in FIG. 2, the stiffener frame 321 may be provided with plural slots, one of which is labeled 338. The slots 338 may be provided to accommodate the placement of the components such as the components 324. In this way, the frame 321 may be brought into engagement with the circuit board 320 and the various components such as the components 324 may project up into one of the openings, such as the slot 338. In this way, the actual surface area of the stiffener frame 321 that seats on the circuit board 320 may be increased to provide greater stiffness while still accommodating the placement of the components 324. The stiffener frame 321 may be composed of the same types of materials and manufactured using the same techniques as disclosed for the other embodiments.

In the foregoing illustrative embodiments, protection for circuit board corners is provided by fabricating notches, e.g., 135a, 135b at board corners, e.g., 130a, 130b and cooperating concave projections, e.g., 140a, 140b of a stiffener frame 121 shown in FIG. 2. However, corner protection may be extended to other geometries. FIG. 6 is a pictorial view of a portion of an alternate exemplary embodiment of a semiconductor chip device 410. Like the other disclosed embodiments, the semiconductor chip device 410 may include a circuit board 420 and a stiffener frame 421. Here, only portions of the circuit board 420 and stiffener frame 421 are visible. In lieu of a notch, the corner 430d of the circuit board 420 is rounded and the stiffener frame 421 has a projection 440d that includes a rounded or concave surface 442d facing the rounded corner 430d. The remaining corners (not visible) of the circuit board 420 and projections (not visible) of the stiffener frame 421 may be similarly rounded. The same types of materials and fabrication techniques disclosed elsewhere herein may be used to construct the circuit board 420 and the stiffener frame 421.

Automated substrate handling machines, such as work holders, and fixtures used therewith, such as boats, may be tailored to integrate the use of any of the disclosed embodiments of the stiffener frames 121, 221, 321 or 421 to prevent damage.

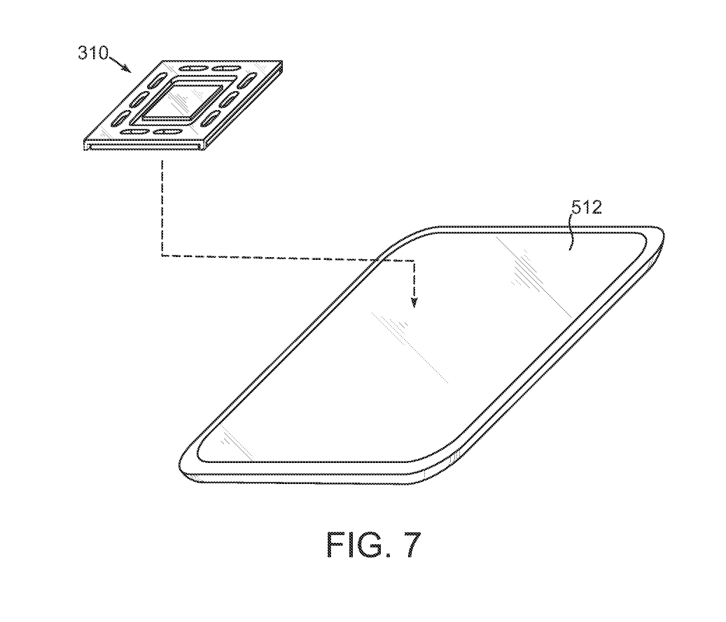

Any of the disclosed embodiments of the semiconductor chip devices 110 and 310 may be mounted on another electronic device. In this regard, attention is now turned to FIG. 7, which depicts the semiconductor chip device 310 exploded from an electronic device 512. The electronic device 512 may be a computer, a server, a hand held device, or virtually any other electronic component.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
fabricating a stiffener frame having a surface adapted to engage a side of a circuit board, the surface including a projection to protect a corner of the circuit board.

2. The method of claim 1, comprising fabricating the stiffener frame with first opening to accommodate an electronic component on the side of the circuit board.

3. The method of claim 2, comprising fabricating the stiffener frame wherein with a second opening lateral to the first opening to accommodate another component on the side.

4. The method of claim 1, comprising fabricating the stiffener frame with the surface including four projections to protect four corners of the circuit board.

5. The method of claim 1, wherein the corner includes a concave notch facing towards the projection.

6. The method of claim 1, wherein the corner is rounded and the projection includes a concave surface facing the rounded corner.

7. The method of claim 1, comprising engaging the side of the circuit board with the surface of the stiffener frame.

8. An apparatus, comprising:
a stiffener frame having a surface adapted to engage a side of a circuit board, the surface including a projection to protect a corner of the circuit board.

9. The apparatus of claim 8, wherein the stiffener frame comprises a central opening to accommodate an electronic component on the side of the circuit board.

10. The apparatus of claim 9, wherein the electronic component comprises a semiconductor chip.

11. The apparatus of claim 8, wherein the circuit board includes four corners and the surface comprises four projections to protect four corners of the circuit board.

12. The apparatus of claim 8, wherein the corner includes a concave notch facing towards the projection.

13. The apparatus of claim 8, wherein the corner is rounded and the projection includes a concave surface facing the rounded corner.

14. The apparatus of claim 8, wherein the surface includes an opening to accommodate a component mounted to the side.

15. An apparatus, comprising:
a circuit board having a side and a corner; and
a stiffener frame positioned on the side and having a projection to protect the corner.

16. The apparatus of claim 15, comprising a semiconductor chip mounted to the side, the stiffener frame including a first opening to accommodate the semiconductor chip.

17. The apparatus of claim 16, wherein stiffener frame includes a second opening to accommodate a component mounted to the side laterally from the semiconductor chip.

18. The apparatus of claim 15, wherein the circuit board includes four corners and the stiffener frame comprises four projections to protect four corners.

19. The apparatus of claim 15, wherein the corner includes a concave notch facing towards the projection.

20. The apparatus of claim 15, wherein the corner is rounded and the projection includes a concave surface facing the rounded corner.
